(19) United States
(12) Patent Application Publication
(10) Pub. No.: US 2024/0332433 A1
(43) Pub. Date: Oct. 3, 2024

(54) CAPACITOR EMBEDDING FOR FLIP CHIP PACKAGES

(71) Applicant: Texas Instruments Incorporated, Dallas, TX (US)

(72) Inventors: Li Jiang, Allen, TX (US); Makarand Ramkrishna Kulkarni, Dallas, TX (US)

(21) Appl. No.: 18/193,037

(22) Filed: Mar. 30, 2023

(51) Int. Cl. H01L 29/94; H01L 21/48; H01L 21/56; H01L 21/768; H01L 23/64; H01L 29/66

(52) U.S. Cl. CPC H01L 29/945; H01L 21/4853; H01L 21/486; H01L 21/563; H01L 21/76838; H01L 23/642; H01L 28/40; H01L 29/66181

(57) ABSTRACT

An electronic device includes a semiconductor die having a side, first conductive terminals along a first portion of the side, and second conductive terminals along a second portion of the side, a substrate having conductive features facing the first portion of the side of the semiconductor die and electrically coupled to respective ones of the first conductive terminals, a capacitor die or a ceramic capacitor having conductive capacitor terminals facing the second portion of the side of the semiconductor die and electrically coupled to respective ones of the second conductive terminals, and a package structure that at least partially encloses the semiconductor die, the substrate and the capacitor die or ceramic capacitor.

### BACKGROUND

Electromagnetic interference (EMI) performance is important for many electrical circuits and packaged electronic devices thereof, such as high speed/high frequency packages. EMI performance can be enhanced by adding capacitors inside an electronic device and/or providing capacitors outside the package, such as on a host printed circuit board. Internal capacitor approaches, such as capacitors within the device package on a flip-chip substrate on the side of the die increase the package size of an electronic device. Also, the EMI performance is typically not optimized due to long connection loops from die connections to internal capacitor terminals or even longer connections to an external board. Another approach involves applying EMI shielding to an exterior of a device package, such as by adding a shield-can to the device, but this inhibits or prevents low profile package designs for compact applications.

### SUMMARY

In one aspect, an electronic device includes a semiconductor die, a substrate, a capacitor die or a ceramic capacitor, and a package structure, where the semiconductor die has a side, first conductive terminals along a first portion of the side, and second conductive terminals along a second portion of the side, the substrate has conductive features facing the first portion of the side of the semiconductor die and electrically coupled to respective ones of the first conductive terminals, the capacitor die or a ceramic capacitor has conductive capacitor terminals facing the second portion of the side of the semiconductor die and electrically coupled to respective ones of the second conductive terminals, and the package structure that at least partially encloses the semiconductor die, the substrate and the capacitor die or ceramic capacitor.

In another aspect, a system includes a circuit board and an electronic device. The electronic device has a semiconductor die, a substrate, a capacitor die or a ceramic capacitor, and a package structure. The semiconductor die has a side, first conductive terminals along a first portion of the side, and second conductive terminals along a second portion of the side, the substrate has conductive features facing the first portion of the side of the semiconductor die and electrically coupled to respective ones of the first conductive terminals, the capacitor die or a ceramic capacitor has conductive capacitor terminals facing the second portion of the side of the semiconductor die and electrically coupled to respective ones of the second conductive terminals, and the package structure at least partially encloses the semiconductor die, the substrate and the capacitor die or ceramic capacitor.

In a further aspect, a method of fabricating an electronic device includes attaching conductive capacitor terminals of a capacitor die or a ceramic capacitor to respective second conductive terminals of a semiconductor die, attaching first conductive terminals of the semiconductor die to respective conductive features of a substrate, and forming a package structure that at least partially encloses the semiconductor die, the substrate and the capacitor die or ceramic capacitor.

### BRIEF DESCRIPTION OF THE DRAWINGS

FIG. 1 is a sectional side elevation view of a packaged electronic device having a capacitor die with conductive metal pillar capacitor terminals flip-chip attached to conductive metal pillar terminals of a semiconductor die and the capacitor die is positioned between first and second substrates according to one embodiment.

FIG. 1A is a sectional top view of the electronic device taken along line 1A-1A of FIG. 1.

FIG. 2 is a flow diagram showing a method of fabricating an electronic device.

FIGS. 3-12 are partial sectional side elevation views of the electronic device of FIGS. 1 and 1A undergoing fabrication processing according to an example implementation of the method of FIG. 2.

FIG. 13 is a sectional side elevation view of a packaged electronic device having a capacitor die with conductive metal pillar capacitor terminals flip-chip attached to conductive metal pillar terminals of a semiconductor die and the capacitor die is positioned in an opening of a laterally surrounding substrate according to another embodiment.

FIG. 13A is a sectional top view of the electronic device taken along line 13A-13A of FIG. 13.

FIG. 14 is a sectional side elevation view of a packaged electronic device having a capacitor die with solder bump terminals flip-chip attached to conductive metal pillar terminals of a semiconductor die and the capacitor die is positioned between first and second substrates according to another embodiment.

FIG. 15 is a sectional side elevation view of a packaged electronic device having a capacitor die with conductive metal pillar terminals flip-chip attached to solder bump terminals of a semiconductor die and the capacitor die is positioned between first and second substrates according to another embodiment.

FIG. 16 is a sectional side elevation view of a packaged electronic device having a ceramic capacitor with terminals attached to conductive metal pillar terminals of a semiconductor die and the ceramic capacitor is positioned between first and second substrates according to another embodiment.

FIG. 17 is a sectional side elevation view of a packaged electronic device having a capacitor die with conductive metal pillar capacitor terminals flip-chip attached to conductive metal pillar terminals of a semiconductor die and a two-part package structure including a molded underfill according to another embodiment.

FIG. 18 is a sectional side elevation view of a packaged electronic device having a capacitor die with conductive metal pillar capacitor terminals flip-chip attached to conductive metal pillar terminals of a semiconductor die along with a molded underfill and a top lid according to another embodiment.

FIG. 19 is a sectional side elevation view of a packaged electronic device having a capacitor die with conductive metal pillar capacitor terminals flip-chip attached to conductive metal pillar terminals of a semiconductor die and the capacitor die is partially exposed through the package structure along the bottom side of the electronic device according to another embodiment.

FIG. 20 is a sectional side elevation view of a packaged electronic device having a capacitor die with conductive metal pillar terminals flip-chip attached to conductive metal pillar terminals of a semiconductor die and the capacitor die is positioned laterally alongside a single substrate between the substrate and a lateral side of the electronic device according to another embodiment.

FIG. 21 is a sectional side elevation view of a packaged electronic device having a capacitor die with conductive metal pillar capacitor terminals flip-chip attached to conductive metal pillar terminals of a semiconductor die along with a laminated organic ceramic substrate.

FIG. 22 is a partial sectional side elevation view of an example trench capacitor (TCAP) die.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means+/−10 percent of the stated value.

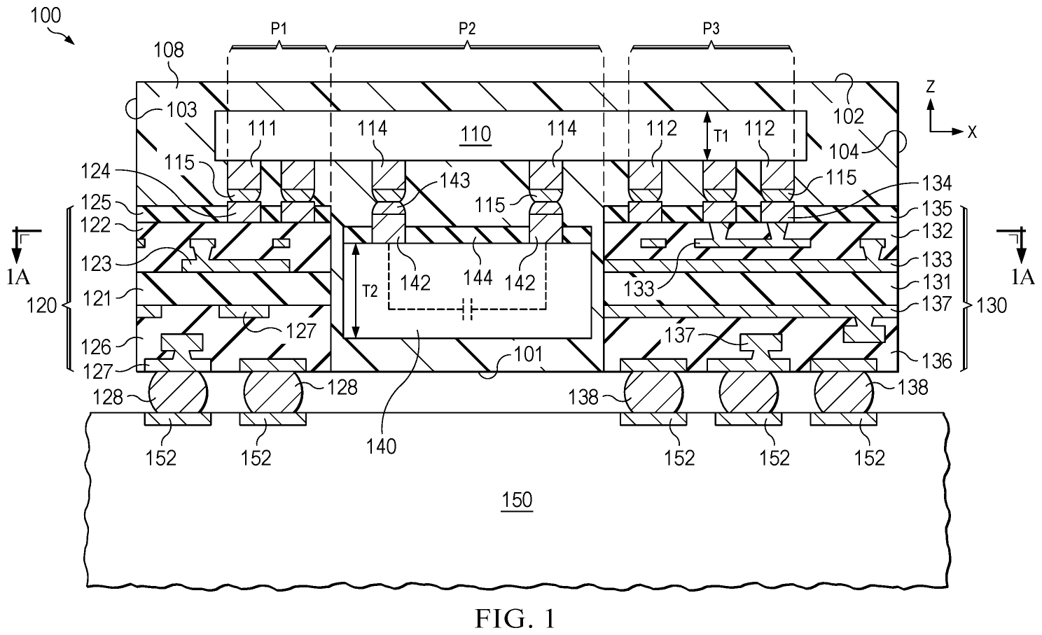

FIGS. 1 and 1A show a packaged electronic device 100 with one or more integrated capacitors to facilitate good EMI performance. FIG. 1 shows the electronic device 100 installed in an example system, such as a smart phone, laptop or desktop computer, a tablet, an automotive system, an industrial system, etc. The electronic device 100 is shown in FIGS. 1 and 1A in an example position or orientation in a three-dimensional space with a first direction X (indicated in FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. As best shown in FIG. 1, the electronic device 100 has opposite first and second (e.g., bottom and top) sides 101 and 102, respectively, which are spaced apart from one another along the third direction Z. The electronic device 100 has laterally opposite third and fourth sides 103 and 104 (FIGS. 1 and 1A) that are spaced apart from one another along the first direction X, and opposite fifth and sixth sides 105 and 106 (FIG. 1A) spaced apart from one another along the second direction Y in the illustrated orientation. The sides 101-106 in one example have substantially planar outer surfaces. In other examples (not shown), one or more of the sides 101-106 have curves, angled features, or other non-planar surface features.

As shown in FIG. 1, the electronic device 100 has a package structure 108, such as a molded plastic structure that forms all or a portion of the second side, upper portions of the lateral sides 103-106, and a middle portion of the first side 101.

The electronic device 100 also includes a semiconductor die 110 shown in FIG. 1. The semiconductor die 110 has generally planar top and bottom sides with a thickness T1 along the third direction Z, and conductive terminals along the bottom side. The semiconductor die 110 includes one or more electrical circuit components (not shown) as well as conductive terminals 111, 112 and 114. At least some of the conductive terminals 111, 112 and 114 provide circuit connections to interconnect other external devices and/or components to a circuit of the electronic device 100. In the example of FIG. 1, the conductive terminals 111, 112 and 114 are conductive metal (e.g., copper, etc.) pillars that extend outward from the bottom side of the semiconductor die 110. This facilitates flip-chip die attachment and soldering to form electrical connections to the circuitry of the electronic device 100. The conductive terminals 111, 112 and 114 of the semiconductor die 110 each have solder 115 applied to the ends thereof, for example, by dipping, printing or other suitable process to allow flip-chip attachment and thermal reflow to make electrical and mechanical connections thereto.

The conductive terminals in the example electronic device 100 include first conductive terminals 111 and associated solder portions 115 along a first portion (e.g., labelled P1 in FIG. 1) of the bottom side of the semiconductor die 110 (e.g., the left portion in the view of FIG. 1), as well as second conductive terminals 114 and corresponding solder portions 115 along a second portion P2 of the bottom side (e.g., the middle portion in FIG. 1), and third conductive terminals 112 and corresponding solder portions 115 along a third (e.g., right) portion P3 of the bottom side of the semiconductor die 110.

The electronic device 100 in FIGS. 1 and 1A includes a first multilevel package substrate 120. In other implementations, a single level substrate can be used and/or a different type of substrate can be used. The first substrate 120 includes multiple dielectric layers or levels with patterned conductive features formed thereon and therebetween to provide circuit signal and power routing for the circuitry of the electronic device 100. The illustrated first substrate 120 has a core (e.g., middle) dielectric layer 121 that may include conductive vias or other conductive structures extending therethrough (not shown), and an upper dielectric level 122 with patterned conductive metal features 123 (e.g., copper or other metal) and upper conductive features 124 facing the first portion P1 of the side of the semiconductor die 110. The upper dielectric level 122 can have a single dielectric layer, such as compression molded dielectric material, or can include multiple dielectric layers with associated conductive metal interconnection features 123 such as traces, vias, etc. The conductive features 124 of the first substrate 120 are electrically coupled by respective solder portions 115 to respective ones of the first conductive terminals 111 of the semiconductor die 110. The first substrate 120 in one example also includes a solder mask layer 125 on a top side of the upper dielectric layer 122 with openings to allow electrical and mechanical connection of the respective conductive features 124 to the first conductive terminals 111 and associated solder portions 115 along a first portion (e.g., labelled P1 in FIG. 1) of the bottom side of the semiconductor die 110, for example, by flip-chip die attach processing such as placement and subsequent thermal reflow to create solder connections as shown in FIG. 1.

The illustrated first substrate 120 also has a lower dielectric level 126 with patterned conductive metal features 127 (e.g., copper or other metal). Certain of the conductive metal features 127 have sides exposed to the bottom or first side 101 of the electronic device 100 to allow electrical connections to a host circuit board, for example, by solder balls 128 in the illustrated flip-chip ball grid array (BGA) configuration of the electronic device 100. The lower dielectric level 126 can have a single dielectric layer, such as compression molded dielectric material, or can include multiple dielectric layers with associated conductive metal interconnection features 127 such as traces, vias, etc. as shown in the example of FIG. 1.

The electronic device 100 in FIGS. 1 and 1A further comprises a second substrate 130 having second conductive features 134 facing the third portion P3 of the side of the semiconductor die 110 and electrically coupled to the respective third conductive terminals 112. The second substrate 130 in FIGS. 1 and 1A is a multilevel package substrate. In other implementations, a single level substrate can be used and/or a different type of substrate can be used. The second substrate 130 includes multiple dielectric layers or levels with patterned conductive features formed thereon and therebetween to provide circuit signal and power routing for the circuitry of the electronic device 100. The second substrate 130 has a core (e.g., middle) dielectric layer 131 that may include conductive vias or other conductive structures extending therethrough (not shown), and an upper dielectric level 132 with patterned conductive metal features 133 (e.g., copper or other metal) and upper conductive features 134 facing the third portion P3 of the side of the semiconductor die 110. The upper dielectric level 132 can have a single dielectric layer, such as compression molded dielectric material, or can include multiple dielectric layers with associated conductive metal interconnection features 133 such as traces, vias, etc.

The conductive features 134 of the second substrate 130 are electrically coupled by respective solder portions 115 to respective ones of the third conductive terminals 112 of the semiconductor die 110. The second substrate 130 in one example also includes a solder mask layer 135 on a top side of the upper dielectric layer 132 with openings to allow electrical and mechanical connection of the respective conductive features 134 to the third conductive terminals 112 and associated solder portions 115 along the third portion P3 of the bottom side of the semiconductor die 110, for example, by flip-chip die attach processing such as placement and subsequent thermal reflow to create the solder connections shown in FIG. 1. The second substrate 130 also has a lower dielectric level 136 with patterned conductive metal features 137 (e.g., copper or other metal). Certain of the conductive metal features 137 have sides exposed to the bottom or second side 101 of the electronic device 100 to allow electrical connections to a circuit board, for example, by further solder balls 138. The lower dielectric level 136 can have a single dielectric layer, such as compression molded dielectric material, or can include multiple dielectric layers with associated conductive metal interconnection features 137 such as traces, vias, etc. as shown in the example of FIG. 1.

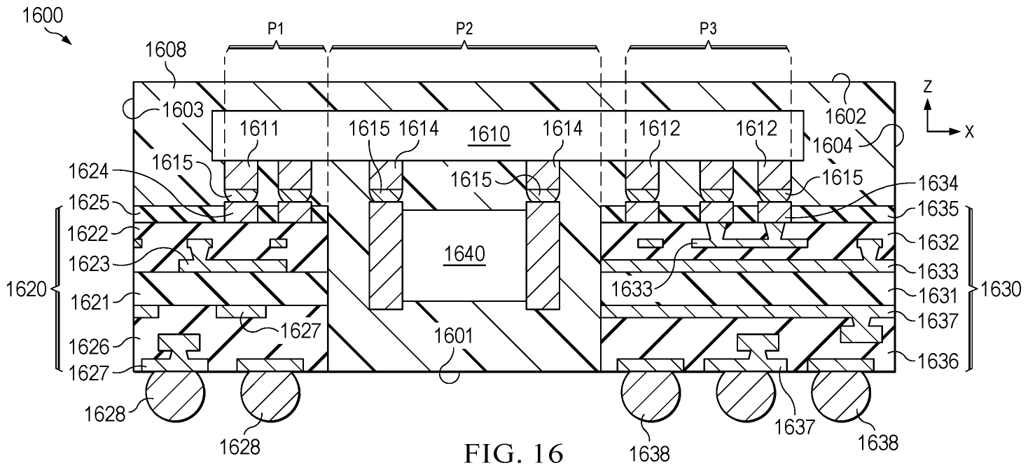

The electronic device 100 also includes a capacitor die 140 with a second thickness T2. The capacitor die 140 includes one or more capacitors connected to the circuitry of the semiconductor die 110 to facilitate good EMI performance of the electronic device 100. The illustrated example has multiple capacitor dies 140 positioned laterally between the respective first and second substrates 120 and 130. The individual capacitor dies 140 have respective sets of conductive capacitor terminals 142 (FIGS. 1 and 1A) and associated solder portions 143 (FIG. 1) that face the second portion P2 of the side of the semiconductor die 110 and are electrically coupled to respective ones of the second conductive terminals 114 and associated solder portions 115. In other examples (e.g., FIG. 16 below), one or more ceramic capacitors can be substituted for the capacitor dic(s) 140. In the illustrated example, the conductive capacitor terminals 142 are further conductive metal pillars that extend toward, and are soldered to, respective ones of the conductive metal pillars 114, for example, via the solder portions 115 and/or 143 by flip-chip die attach processing such as placement and subsequent thermal reflow to create solder connections as shown in FIG. 1. In one implementation, the capacitor die 140 has a protective coating layer 144, for example, polyimide, on a top side of the capacitor die 140 with openings to allow electrical and mechanical connection of the respective conductive capacitor terminals 142 to the second conductive terminals 114 and associated solder portions 115 along the second portion P2 of the bottom side of the semiconductor die 110, for example, by flip-chip die attach processing such as placement and subsequent thermal reflow to create the solder connections shown in FIG. 1.

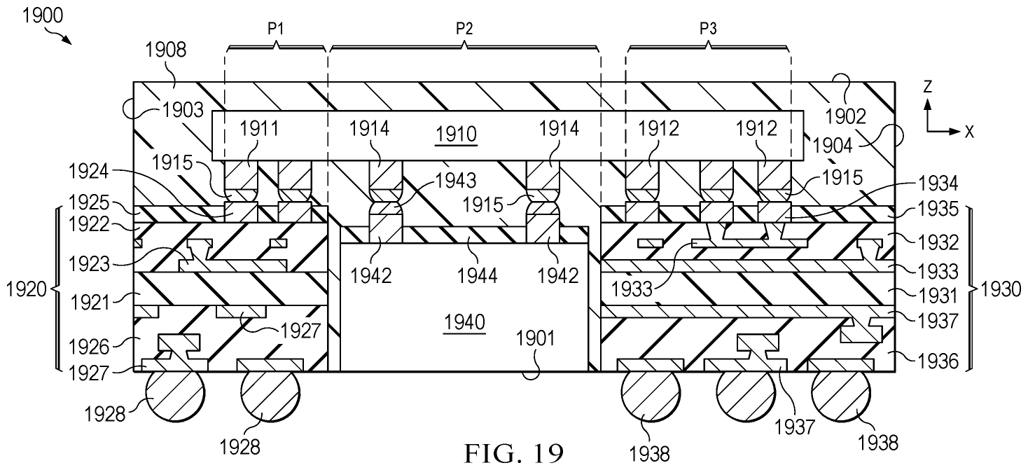

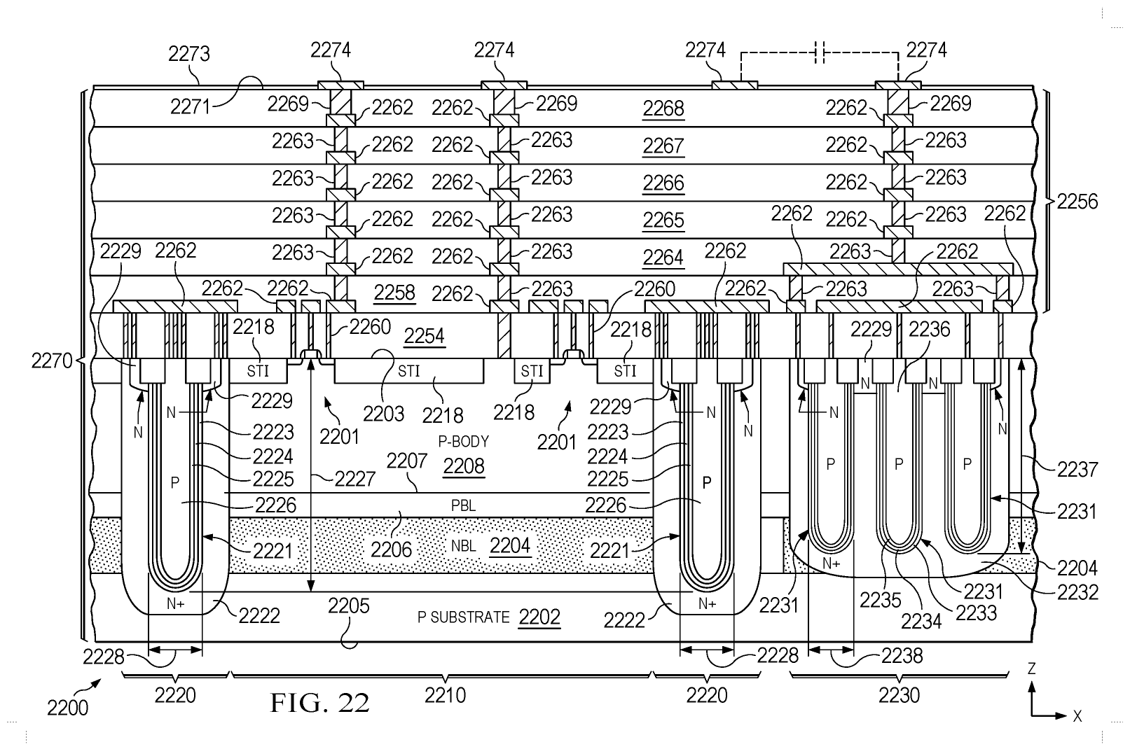

In one implementation, the capacitor die 140 is a trench capacitor (TCAP) die that includes one or more trench capacitors formed in a semiconductor body of the capacitor die 140, for example, as described further below in connection with FIG. 22. The position of the capacitor die 140 in close proximity to the semiconductor die 110 shortens the connection of the capacitor(s) of the capacitor die 140 to the circuitry of the semiconductor die for reduced circuit inductance and improved EMI performance while facilitating compact electronic device packaging. The second thickness T2 of the capacitor die 140 can be tailored for specific device designs, for example, by backgrinding during wafer processing to produce the capacitor die 140 with a thickness T2 that is less than the thicknesses of the substrates 120 and 130 as shown in the example of FIG. 1. In this example, the molded package structure 108 at least partially encloses the semiconductor die 110, the substrates 120 and 130 and the capacitor die 140 and covers the bottom side of the capacitor die 140. In other examples, the bottom of the capacitor die can be exposed, for example, as described further below in connection with FIG. 19.

The example electronic device 100 has the capacitor die 140 and the semiconductor die 110 flip-chip attached to one another with the semiconductor die 110 also flip-chip attached to the respective first and second multilevel package substrates 120 and 130. The capacitor die 140 has conductive metal pillar capacitor terminals 142 flip-chip attached to the conductive metal pillar terminals 114 of the semiconductor die 110 and the capacitor die 140 is positioned laterally between the first and second substrates 120 and 130. The flip-chip BGA example electronic device 100 is installed on a circuit board 150 in the system of FIG. 1, with respective ones of the solder balls 128 and 138 soldered to provide mechanical and electrical connections to conductive metal board pads 152 of the circuit board 150. The integration of the capacitor die 140 in the packaged electronic device 100 advantageously provides a compact system implementation with good EMI performance without requiring external capacitors on the circuit board 150 and the example design does not require extra space for EMI capacitors on the substrates 120 or 130.

Integration of a capacitor connected to the semiconductor die 110, whether a capacitor die 140 (e.g., including one or more trench capacitors or other on-die capacitor types) or one or more separate capacitor components (e.g., a ceramic capacitor as described further below in connection with FIG. 16) can help EMI performance in flip-chip BGA electronic devices (e.g., the electronic device 100 and other BGA devices described herein) as well as in other types and forms of packaged electronic devices, including without limitation flat pack topologies (e.g., quad flat no-lead (QFP) devices), small outline packages (e.g., thin shrink small outline package (TSSOP) devices), etc. Certain example integrations flip-chip attach a TCAP die (e.g., capacitor die 140) on the bottom side of the semiconductor die 110, where the TCAP die can be back ground to meet package profile requirements of a given design. This provides advantages compared to mounting a TCAP die on the top side of the semiconductor die, which would increase the overall device height (e.g., along the third direction Z) and/or could decrease the performance of the top mounted TCAP die if the TCAP die were back ground to a very small thickness to reduce the package height. Described examples (e.g., the electronic device 100 in FIGS. 1 and 1A) can accommodate integration of relatively thick capacitor dies (e.g., 140) and/or thick ceramic capacitors (e.g., FIG. 16 below) by positioning the capacitor or capacitor die at least partially laterally alongside the substrate or substrates (e.g., 120 and 130 above) where the capacitor/capacitor die thickness (e.g., T2 in FIG. 1) can be close to the substrate thickness. Multiple substrates can be used to accommodate close positioning of the capacitor or capacitor die 140 to the respective second conductive terminals 114 of the semiconductor die 110 to provide short signal routing without any intervening substrate signal routing to reduce loop inductance and improve EMI performance of the electronic device 100. The described examples can be significantly more cost effective and compact compared to approaches using a substrate with embedded capacitors since the embedded substrate has high cost, long lead time, and capacity risks from substrate manufacturing techniques.

The loop inductance Lₗₒₒₚ for a current path going down one plane and back the other depends on the partial self-inductance of each plane path and the partial mutual inductance between them. The wider the planes, the more spread out the current distribution, the lower the partial self-inductance of each plane, and the lower the loop inductance. The longer the planes, the larger their partial self-inductance and the larger the loop inductance. The closer the planes, the larger their mutual inductance and the lower the loop inductance. For the case of wide conductors, where the width w is much larger than their spacing h (w>>h), the loop inductance between two planes is to a very good approximation given by the following equation (1):

$${L}_{loop} = {μ}_{0} h ( Len / w ) , \qquad ( 1 )$$

where Lₗₒₒₚ is the loop inductance in nH, μ₀ is the permeability of free space (32 pH/mil), h is the spacing between the planes in mils, and Len is the distance between the capacitor and the die in mils. In disclosed examples, according to equation (1), Lₗₒₒₚ typically should be less than 10% of the loop inductance found using the side-placement method with capacitors on the top side of a substrate to one side of the semiconductor die, where typical side placement makes the distance (“Len”) between the capacitor and the die on the level of several mm to several cm. In contrast, the distance of described examples should be less than 150 um. Implementations of the described examples can provide compact packaging solutions that achieve much lower loop inductance and better EMI performance with little or no increase in manufacturing cost or complexity for a variety of different electronic device packaging topologies.

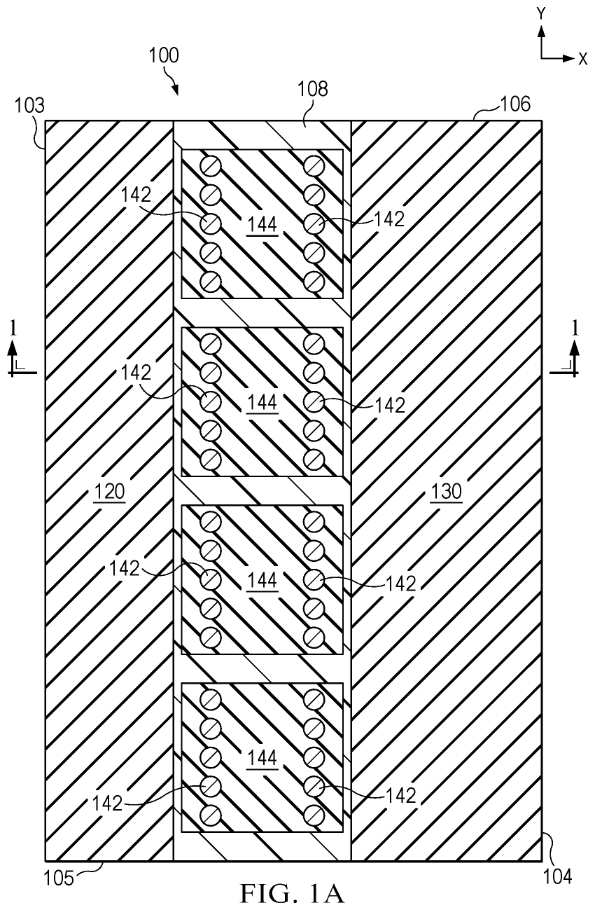

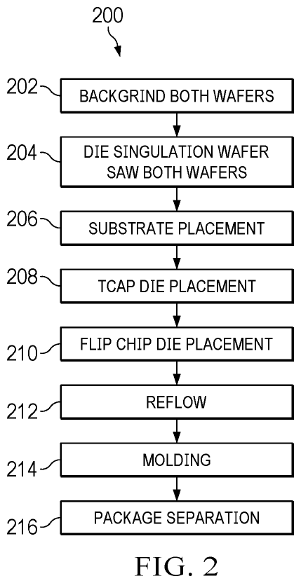

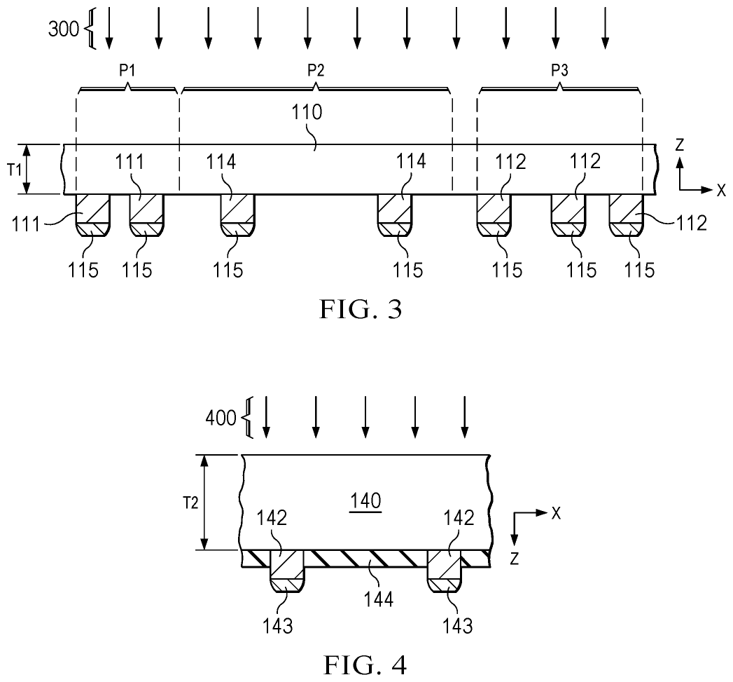

Referring also to FIGS. 2-12, FIG. 2 shows a method 200 of fabricating an electronic device and FIGS. 3-12 show the flip-chip BGA electronic device 100 of FIGS. 1 and 1A undergoing fabrication processing according to an example implementation of the method 200. The method 200 in one example includes wafer processing to fabricate first and second wafers corresponding to ultimately separated instances of the semiconductor die 110 and the capacitor die 140, and the wafers undergo separate back grinding operations at 202 in FIG. 2. FIG. 3 shows an example of a first wafer with multiple unit areas individually corresponding to respective instances of the semiconductor die 110 undergoing a first back grinding process 300 that sets the first thickness T1 of the subsequently separated semiconductor die instances 110. FIG. 4 shows an example of a second wafer with multiple unit areas individually corresponding to respective instances of the capacitor die 140 undergoing a second back grinding process 400 that sets the second thickness T2 of the subsequently separated capacitor die instances 140.

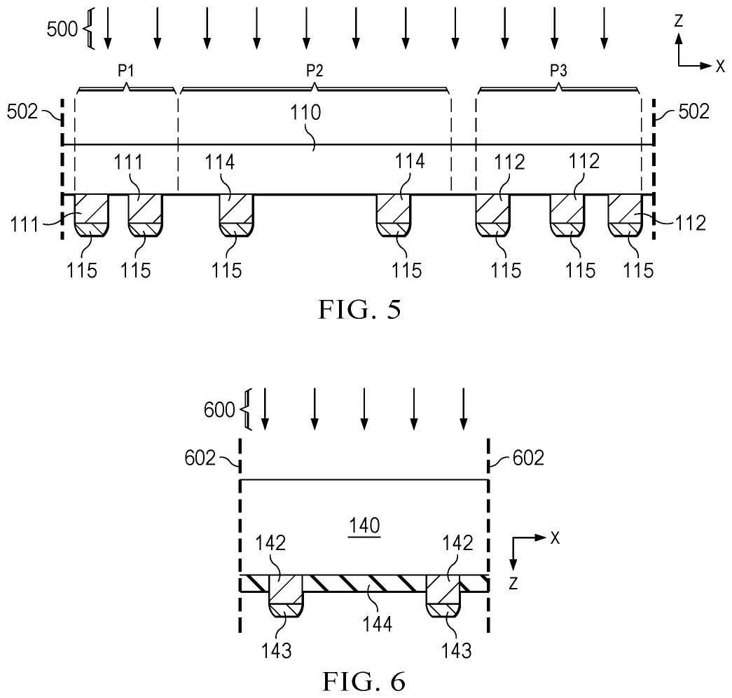

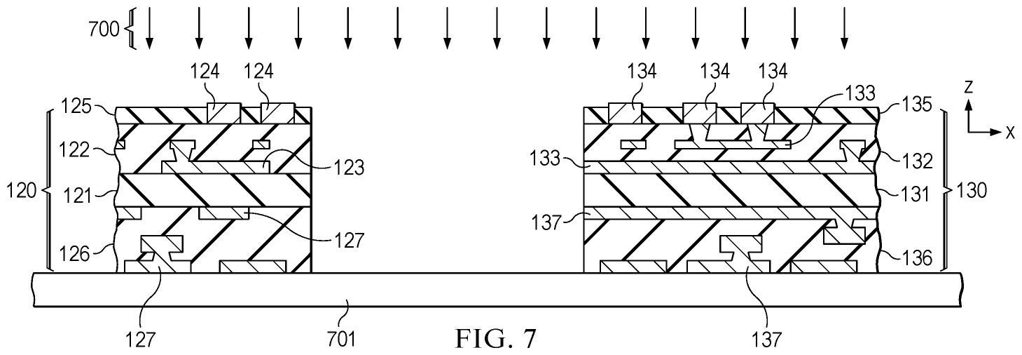

The example implementation of the method 200 continues at 204 in FIG. 2 with dic singulation or separation processing perform separately for the first and second wafers. FIG. 5 shows an example of the first wafer undergoing a cutting process 500, such as saw cutting, laser cutting, etching, or other cutting operation that cuts along lines 502 and separates individual instances of the semiconductor die 110 from the starting first wafer. FIG. 6 shows an example of the second wafer undergoing a cutting process 600 (e.g., saw cutting, laser cutting, etching, etc.) that cuts along lines 602 in order to separate individual instances of the capacitor die 140 from the starting second wafer.

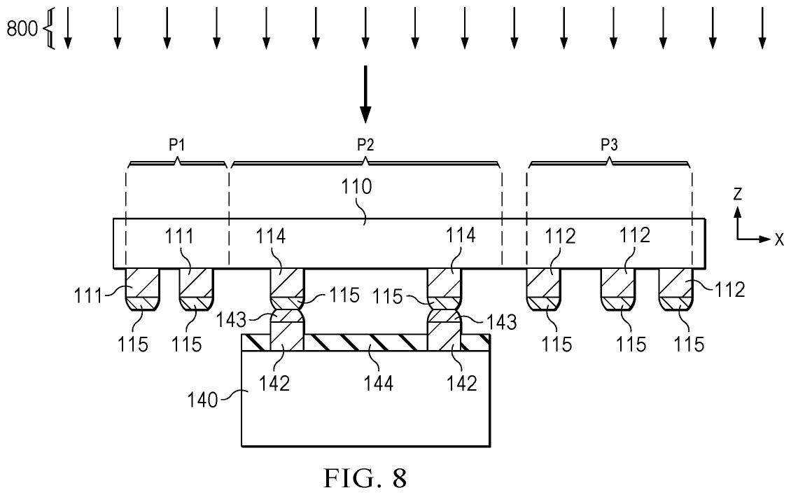

At 206 in FIG. 2, the example implementation of the method 200 includes substrate placement. The fabrication of individual instances of the packaged electronic device 100 in one example includes processing of an array of individual unit areas that each include an instance of the first multilevel package substrate 120 and the second multilevel package substrate 130. FIG. 7 shows one example, in which a substrate placement process 700 is performed that positions the first and second substrates 120 and 130 on a carrier structure 701, such as an adhesive tape or other suitable fixture. The array in one example includes rows and columns of unit areas positioned on a single carrier structure 701. The subsequently separated unit areas can initially be formed as joined structures, or even a single structure, that includes the layers and levels of the prospective first and second substrates 120 and 130 that are fabricated together and installed on the carrier structure 701, and the first and second substrates 120 and 130 are subsequently separated later in the process.

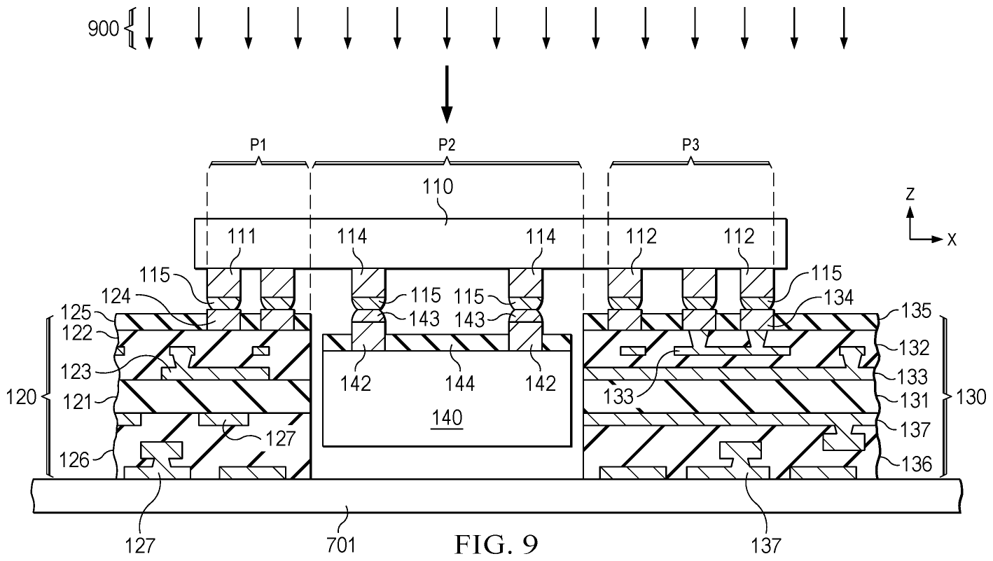

At 208 in FIG. 2, the method 200 includes a capacitor die attachment that attaches individual instances of the semiconductor die 110 and respective instances of the capacitor die 140 to form electrical and mechanical interconnections thereof. FIG. 8 shows one example, in which a first flip-chip die attach process 800 is performed that attaches the conductive capacitor terminals 142 and associated solder portions 143 of the capacitor die 140 to respective second conductive terminals 114 and associated solder portions 115 of the semiconductor die 110. In one example, the attachment is performed using automated pick and place equipment (not shown). The first attach process 800 in one example can include a separate thermal reflow step to form solder connections between the terminals 114 and 142.

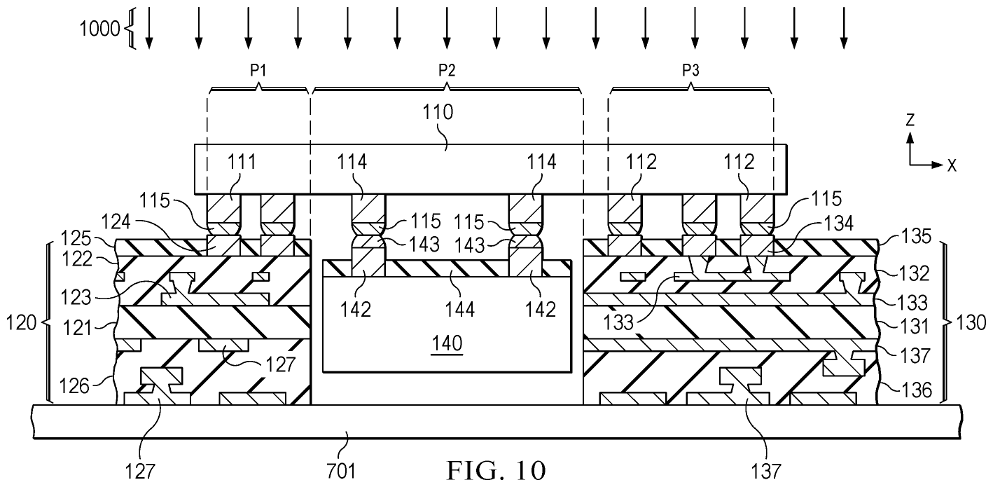

The method 200 continues at 210 in FIG. 2 with a second die attach process that attaches the semiconductor die/capacitor die subassembly to the first and second substrates 120 and 130 in each unit area of the processed multilevel package substrate panel array. FIG. 9 shows one example, in which a second flip-chip die attach process 900 is performed that attaches a semiconductor die/capacitor die subassembly to the top sides of the first and second substrates 120 and 130 in each unit area, for example, using automated pick and place equipment (not shown). The subassembly is aligned and translated downward along the indicated line in FIG. 9 in each respective unit area of the processed panel array to attach the first conductive terminals 111 along the first portion P1 and the third conductive terminals 112 along the second portion P3 of the lower side of the semiconductor die 110 to the corresponding respective conductive features 124 and 134 of a substrates 120 and 130.

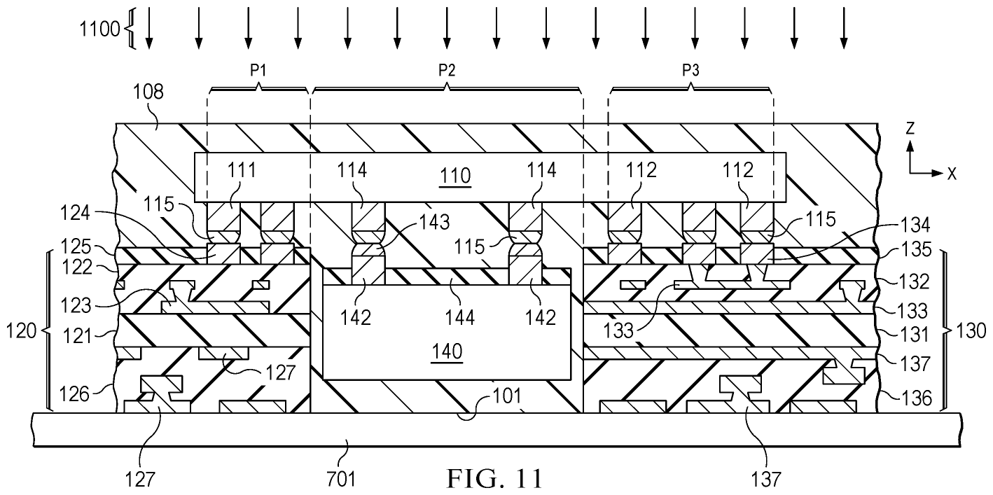

At 212 in FIG. 2, the method 200 continues with a thermal process to reflow the solder portions 115 and 143 to form solder connections between the respective conductive terminals 111, 112 and the substrate conductive features 124 and 134, respectively. FIG. 10 shows one example, in which a thermal reflow process 1000 is performed that reflows solder portions 115 to provide mechanical attachment and electrical connection of the metal pillar conductive terminals 111, 112 and conductive features 124 and 134 of the respective substrates 120 and 130, the thermal process 1000 may also reflow the solder portions 115 and 143 to form the final solder connections between the metal pillar conductive terminals 114 of the semiconductor die 110 and the metal pillar conductive capacitor terminals 142 of the capacitor die 140 in each unit area of the processed panel array.

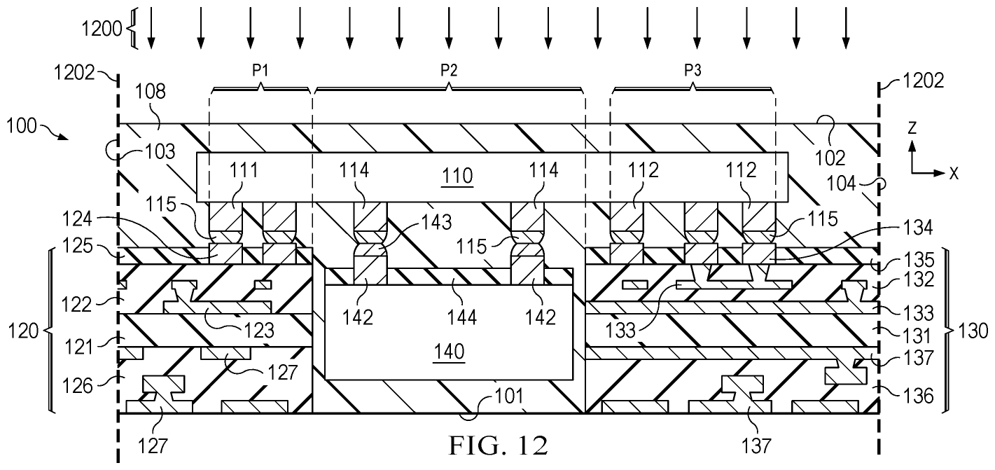

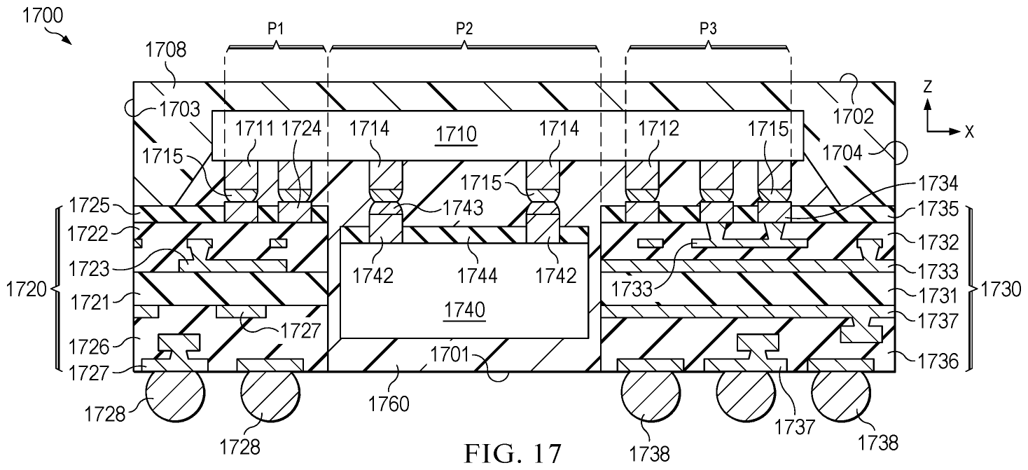

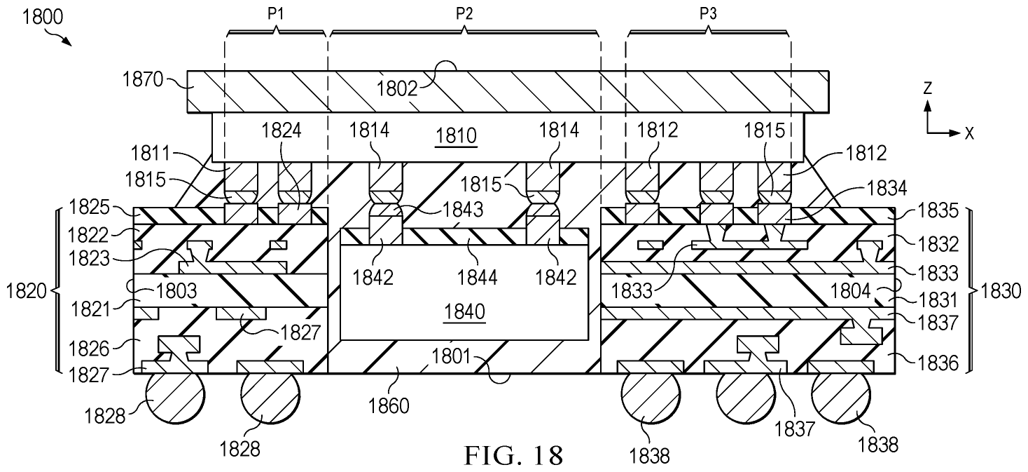

The method 200 continues at 214 in FIG. 2 with one or more molding steps or operations to form a molded package structure. In one implementation, the molding at 214 can be performed using any suitable molding equipment. In one implementation, a single mold cavity can be used for an entire panel array or multiple cavities can be used for individual unit areas thereof or groups of unit areas, such as column-wise mold cavities, or combinations thereof. FIG. 11 shows one example, in which a molding process 1100 is performed to form the package structure 108 that at least partially encloses the semiconductor die 110, the substrate 120, 130 and the capacitor die 140 in each unit area of the panel array. In one example, the panel array remains positioned on the carrier support structure 701 as shown in FIG. 11. In another implementation, the panel array is removed from the carrier 701 and installed on a bottom feature of the molding equipment, and a top mold structure (not shown) is installed which has one or more cavities to define the tops of the molded structures 108 (and to define all or portions of lateral sides thereof in certain multi-cavity implementations). In certain examples, the molding processing at 214 in FIG. 2 can include separate formation of multiple molded portions of a package structure, such as initial mold underfill formation, followed by a subsequent top molding process (e.g., FIG. 17 below), or the molding at 214 creates a mold underfill followed by attachment of a metal lid over at least a portion of a second side of the semiconductor die 110 without forming a second top mold structure (e.g., FIG. 18 below). In one example, the method 200 includes forming a mold underfill at 214 that at least partially encloses the semiconductor die 110, the substrate 120, 130 and the capacitor die 140 (e.g., FIGS. 17 and 18).

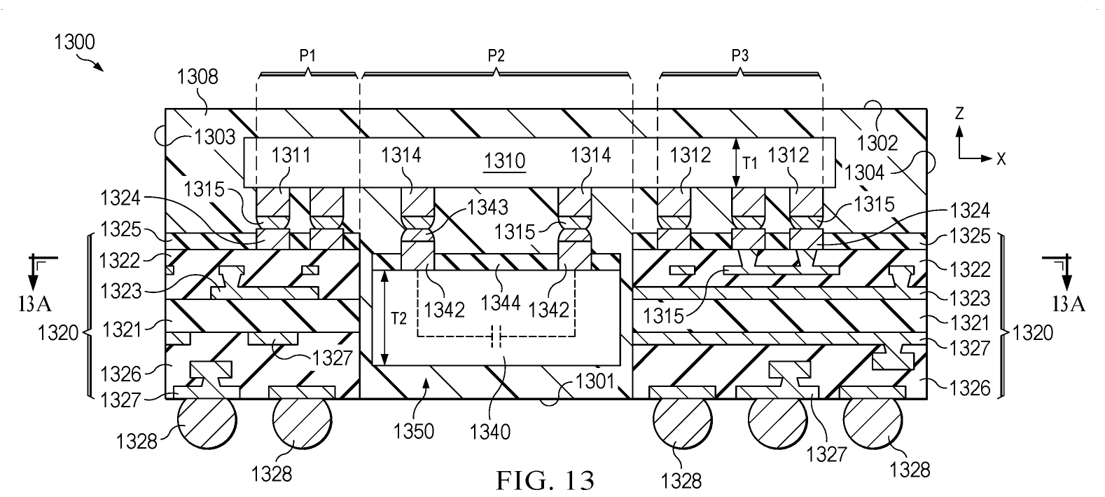

The method 200 in one example also includes package separation at 216 in FIG. 2 to separate individual packaged electronic devices from the processed panel array structure, for example, to form strip or panel array based flip-chip chip scale package (FCCSP) devices (not shown). FIG. 12 shows one example, in which a saw cutting separation process 1200 is performed that separates individual packaged electronic devices 100 from the processed panel array structure by cutting along lines 1202. Any suitable cutting or separation process can be used, including without limitation saw cutting, laser cutting, chemical etching, etc. or combinations thereof. In certain examples, the method 200 can also include final device testing after package separation at 216 and/or wafer level testing (e.g., before or after 202 in FIG. 2). In certain implementations, the package separation processing at 216 can be omitted, for example, to form certain flip-chip ball grid array (FCBGA) devices.

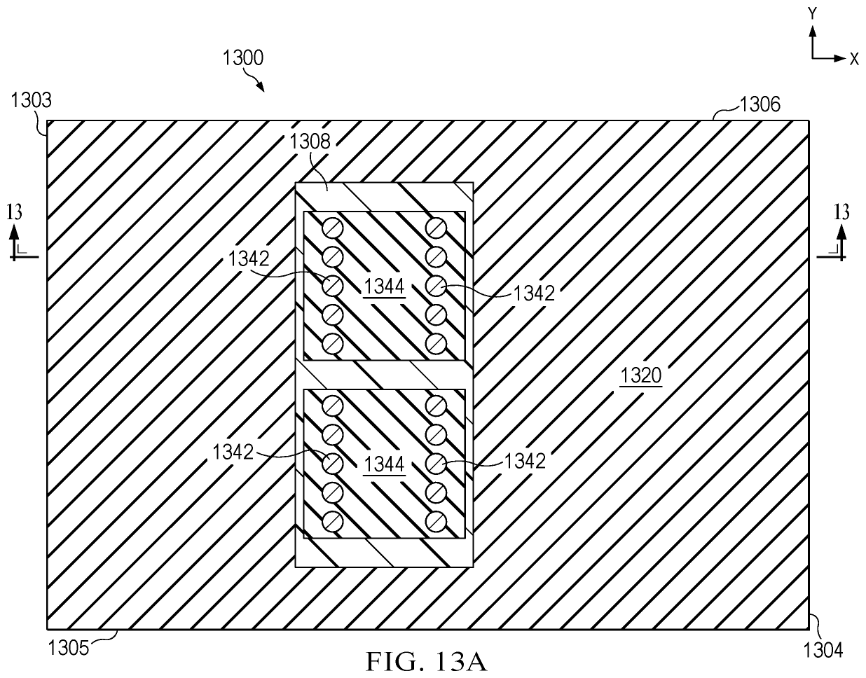

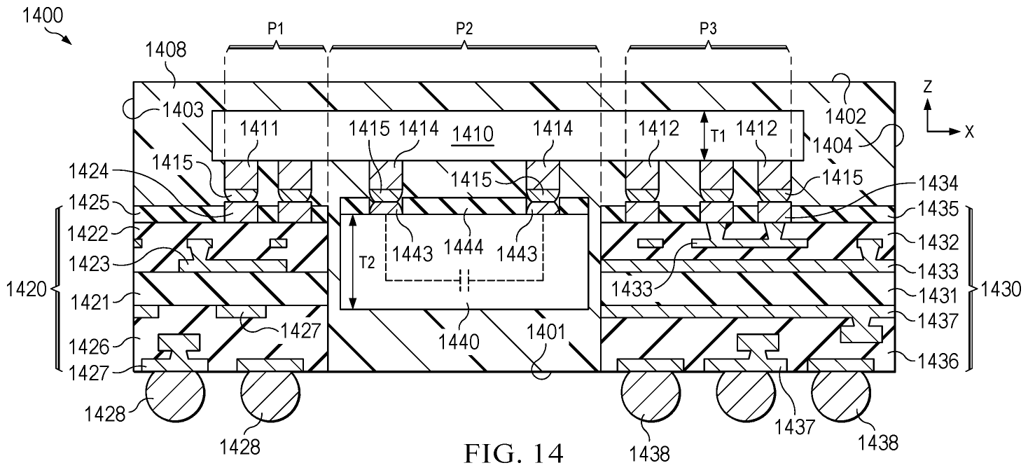

FIGS. 13-21 show further example electronic devices with integrated capacitors and/or capacitor dies directly connected to a semiconductor die to facilitate EMI performance in a compact package structure. The electronic device 1300 is shown in FIGS. 13 and 13A and other example electronic devices are shown in FIGS. 14-21 in respective example positions or orientations in a three-dimensional space with a first direction X, a perpendicular (orthogonal) second direction Y, and a third direction Z that is perpendicular (orthogonal) to the respective first and second directions X and Y, where structures or features along any two of these directions are orthogonal to one another. These electronic device examples have opposite first and second sides (e.g., bottom and top sides 1301 and 1302 in FIG. 13) spaced apart from one another along the third direction Z, as well as laterally opposite third and fourth sides (e.g., 1303 and 1304 in FIGS. 13 and 13A) spaced apart from one another along the first direction X, and opposite fifth and sixth sides (e.g., sides 1305 and 1306 in FIG. 13A) spaced apart from one another along the second direction Y in the illustrated orientation. In the below examples of FIGS. 13-21, the device sides (e.g., 1301-1306 in FIGS. 13 and 13A) in one example have substantially planar outer surfaces. In other examples (not shown), one or more of the sides of the packaged electronic device have curves, angled features, or other non-planar surface features.

FIGS. 13 and 13A a show respective sectional side and top views of the example electronic device 1300, where the top view of FIG. 13A a is taken along the line 13A-13A of FIG. 13, and the sectional side view of FIG. 13 is taken along line 13-13 in FIG. 13A. The example electronic device 1300 uses a single substrate 1320 and has a capacitor die 1340 with conductive metal pillar capacitor terminals 1342 flip-chip attached to conductive metal pillar terminals 1314 of a semiconductor die 1310 and the capacitor die 1340 is positioned or otherwise located in an opening 1350 of a laterally surrounding single substrate 1320 according to another embodiment. As further shown in the top view of FIG. 13A, the illustrated example has multiple instances of the capacitor die 1340 and the single substrate 1320 laterally surrounds the capacitor dies 1340 within the opening 1350 of the substrate 1320. Is a sectional top view of the electronic device taken along line 13A-13A of FIG. 13. As shown in FIG. 13, the electronic device 1300 has a package structure 1308, such as a molded plastic structure that forms all or a portion of the second side, upper portions of the lateral sides 1303-1306, and a middle portion of the first side 1301.

The electronic device 1300 also includes a semiconductor die 1310 shown in FIG. 13. The semiconductor die 1310 has generally planar top and bottom sides with a thickness T1 along the third direction Z, and conductive terminals along the bottom side. The semiconductor die 1310 includes one or more electrical circuit components (not shown) as well as conductive terminals 1311, 1312 and 1314. At least some of the conductive terminals 1311, 1312 and 1314 provide circuit connections to interconnect other external devices and/or components to a circuit of the electronic device 1300. In the example of FIG. 13, the conductive terminals 1311, 1312 and 1314 are conductive metal (e.g., copper, etc.) pillars that extend outward from the bottom side of the semiconductor die 1310. This facilitates flip-chip die attachment and soldering to form electrical connections to the circuitry of the electronic device 1300b (e.g., at 208 and 210 in FIG. 2 above). The conductive terminals 1311, 1312 and 1314 of the semiconductor die 1310 each have solder 1315 applied to the ends thereof, for example, by dipping, printing or other suitable process to allow flip-chip attachment and thermal reflow to make electrical and mechanical connections thereto. The conductive terminals in the example electronic device 1300 include first conductive terminals 1311 and associated solder portions 1315 along a first portion (e.g., labelled P1 in FIG. 13) of the bottom side of the semiconductor die 1310 (e.g., the left portion in the view of FIG. 13), as well as second conductive terminals 1314 and corresponding solder portions 1315 along a second portion P2 of the bottom side (e.g., the middle portion in FIG. 13), and third conductive terminals 1312 and corresponding solder portions 1315 along another part of the first (e.g., right) portion P1 of the bottom side of the semiconductor die 1310.

The electronic device 1300 in FIGS. 13 and 13A includes a multilevel package substrate 1320. In other implementations, a single level substrate can be used and/or a different type of substrate can be used. The substrate 1320 includes multiple dielectric layers or levels with patterned conductive features formed thereon and therebetween to provide circuit signal and power routing for the circuitry of the electronic device 1300. The illustrated substrate 1320 has a core (e.g., middle) dielectric layer 1321 that may include conductive vias or other conductive structures extending therethrough (not shown), and an upper dielectric level 1322 with patterned conductive metal features 1323 (e.g., copper or other metal) and upper conductive features 1324 facing the first portion P1 of the side of the semiconductor die 1310. The upper dielectric level 1322 can have a single dielectric layer, such as compression molded dielectric material, or can include multiple dielectric layers with associated conductive metal interconnection features 1323 such as traces, vias, etc. The conductive features 1324 of the first substrate 1320 are electrically coupled by respective solder portions 1315 to respective ones of the first conductive terminals 1311 and 1312 of the semiconductor die 1310. The first substrate 1320 in one example also includes a solder mask layer 1325 on a top side of the upper dielectric layer 1322 with openings to allow electrical and mechanical connection of the respective conductive features 1324 to the first conductive terminals 1311, 1312 and associated solder portions 1315 along a first portion (e.g., labelled P1 in FIG. 13) of the bottom side of the semiconductor die 1310, for example, by flip-chip die attach processing such as placement and subsequent thermal reflow to create solder connections as shown in FIG. 13. The substrate 1320 also has a lower dielectric level 1326 with patterned conductive metal features 1327 (e.g., copper or other metal). Certain of the conductive metal features 1327 have sides exposed to the bottom or first side 1301 of the electronic device 1300 to allow electrical connections to a host circuit board, for example, by solder balls 1328 in the illustrated flip-chip ball grid array (BGA) configuration of the electronic device 1300. The lower dielectric level 1326 can have a single dielectric layer, such as compression molded dielectric material, or can include multiple dielectric layers with associated conductive metal interconnection features 1327 such as traces, vias, etc. as shown in FIG. 13.

The electronic device 1300 also includes a capacitor die 1340 with a second thickness T2. The capacitor die 1340 includes one or more capacitors connected to the circuitry of the semiconductor die 1310 to facilitate good EMI performance of the electronic device 1300. The illustrated example has multiple capacitor dies 1340 positioned or otherwise located in the substrate opening 1350. The individual capacitor dies 1340 have respective sets of conductive capacitor terminals 1342 (FIGS. 13 and 13A) and associated solder portions 1343 (FIG. 13) that face the second portion P2 of the side of the semiconductor die 1310 and are electrically coupled to respective ones of the second conductive terminals 1314 and associated solder portions 1315. In other examples (e.g., FIG. 16 below), one or more ceramic capacitors can be substituted for the capacitor die(s) 1340. In the illustrated example, the conductive capacitor terminals 1342 are further conductive metal pillars that extend toward, and are soldered to, respective ones of the conductive metal pillars 1314, for example, via the solder portions 1315 and/or 1343 by flip-chip die attach processing such as placement and subsequent thermal reflow to create solder connections as shown in FIG. 13 (e.g., at 208 in FIG. 2 above). In one implementation, the capacitor die 1340 has a protective coating layer 1344, for example, polyimide, on a top side of the capacitor die 1340 with openings to allow electrical and mechanical connection of the respective conductive capacitor terminals 1342 to the second conductive terminals 1314 and associated solder portions 1315 along the second portion P2 of the bottom side of the semiconductor die 1310, for example, by flip-chip die attach processing such as placement and subsequent thermal reflow to create the solder connections shown in FIG. 13.

In one implementation, the capacitor die 1340 is a trench capacitor (TCAP) die that includes one or more trench capacitors formed in a semiconductor body of the capacitor die 1340 (e.g., FIG. 22 below). The position of the capacitor die 1340 in close proximity to the semiconductor die 1310 shortens the connection of the capacitor(s) of the capacitor die 1340 to the circuitry of the semiconductor die 1310 for reduced circuit inductance and improved EMI performance while facilitating compact electronic device packaging. The second thickness T2 of the capacitor die 1340 can be tailored for specific device designs, for example, by backgrinding during wafer processing to produce the capacitor die 1340 with a thickness T2 that is less than the thicknesses of the substrate 1320 as shown in the example of FIG. 13. In this example, the molded package structure 1308 at least partially encloses the semiconductor die 1310, the substrate 1320 and the capacitor die 1340 and covers the bottom side of the capacitor die 1340. In other examples, the bottom of the capacitor die can be exposed (e.g., FIG. 19 below).

The example electronic device 1300 has the capacitor die 1340 and the semiconductor die 1310 flip-chip attached to one another with the semiconductor die 1310 also flip-chip attached to the multilevel package substrate 1320. The capacitor die 1340 has conductive metal pillar capacitor terminals 1342 flip-chip attached to the conductive metal pillar terminals 1314 of the semiconductor die 1310 and the capacitor die 1340 is positioned within the opening 1350 of the substrate 1320.

FIG. 14 shows another packaged electronic device 1400 having respective bottom and top sides 1401 and 1402, laterally opposite sides 1403 and 1404, a molded package structure 1408, a capacitor die 1440 with solder bump terminals 1443 flip-chip attached to conductive metal pillar terminals 1414 of a semiconductor die 1410 and the capacitor die 1440 is positioned between first and second substrates 1420 and 1430 according to another embodiment. Apart from these noted differences and differences apparent from the figures, various structures, dimensions, and/or features 1401-1404, 1408, 1410-1412, T1, P1, P2, P3, 1414, 1415, 1420-1428, 1430-1438, 1440, T2, 1443 and 1444 of the electronic device 1400 in FIG. 14 correspond to the respective structures, dimensions, and/or features 101-104, 108, 110-112, T1, P1, P2, P3, 114, 115, 120-128, 130-138, 140, T2, 143 and 144 described above in connection with the electronic device 100 of FIGS. 1 and 1A.

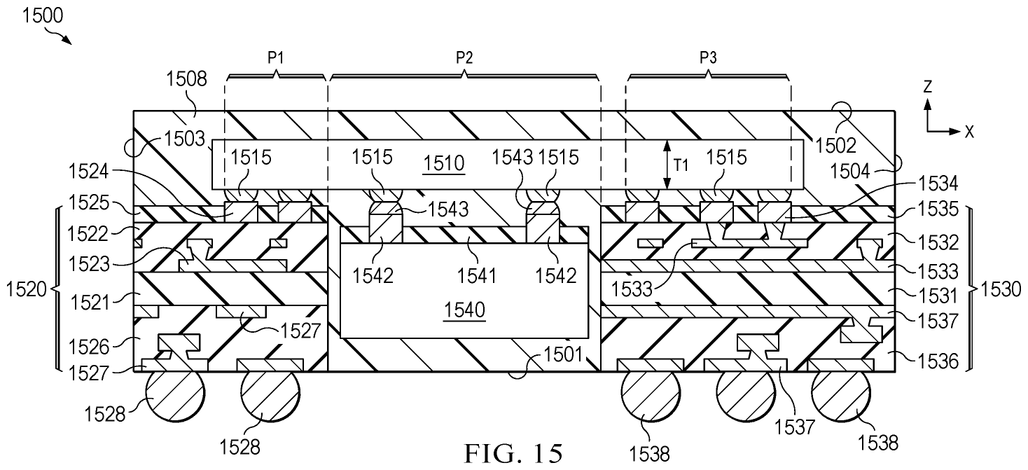

FIG. 15 shows another packaged electronic device 1500 having respective bottom and top sides 1501 and 1502, laterally opposite sides 1503 and 1504, a molded package structure 1508, a capacitor die 1540 with conductive metal pillar capacitor terminals 1542 and associated solder portions 1543 flip-chip attached to solder bump terminals 1515 of a semiconductor die 1510 and the capacitor die 1540 is positioned between respective first and second substrates 1520 and 1530 according to another embodiment. Apart from these noted differences and differences apparent from the figures, various structures, dimensions, and/or features 1501-1504, 1508, 1510-1512, T1, P1, P2, P3, 1515, 1520-1528, 1530-1538, 1540, T2, 1543 and 1544 of the electronic device 1500 in FIG. 15 correspond to the respective structures, dimensions, and/or features 101-104, 108, 110-112, T1, P1, P2, P3, 115, 120-128, 130-138, 140, T2, 143 and 144 described above in connection with the electronic device 100 of FIGS. 1 and 1A.

FIG. 16 shows another packaged electronic device 1600 having respective bottom and top sides 1601 and 1602, laterally opposite sides 1603 and 1604, a molded package structure 1608, a ceramic capacitor 1640 attached to conductive metal pillar terminals 1614 of a semiconductor die 1610 and the ceramic capacitor 1640 is positioned between first and second substrates 1620 and 1630 according to another embodiment. Apart from these noted differences and differences apparent from the figures, various structures, dimensions, and/or features 1601-1604, 1608, 1610-1612, T1, P1, P2, P3, 1614, 1615, 1620-1628, 1630-1638, T2, 1643 and 1644 of the electronic device 1600 in FIG. 16 correspond to the respective structures, dimensions, and/or features 101-104, 108, 110-112, T1, P1, P2, P3, 114, 115, 120-128, 130-138, T2, 143 and 144 described above in connection with the electronic device 100 of FIGS. 1 and 1A.

FIG. 17 shows another packaged electronic device 1700 having respective bottom and top sides 1701 and 1702, laterally opposite sides 1703 and 1704, a two part molded package structure with a second molded underfill portion 1760 and a first (e.g., top) molded portion 1708, a capacitor die 1740 with conductive metal pillar terminals 1742 and associated solder portions 1743 flip-chip attached to conductive metal pillar terminals 1714 of a semiconductor die 1710 and the capacitor die 1740 is positioned between first and second substrates 1720 and 1730 according to another embodiment. This example uses a molded flip-chip package with molded underfill 1760 and can be applied as shown in FIG. 17 to flip-chip packages with capillary underfill under a top mold compound or with a lid structure as shown in FIG. 18 below. The package structure in this example has the first molded structure 1708 that at least partially encloses the semiconductor die 1710 and the substrates 1720 and 1730, as well as the mold underfill 1760 that at least partially encloses the semiconductor die 1710, the substrates 1720 and 1730 and the capacitor die 1740. Apart from these noted differences and differences apparent from the figures, various structures, dimensions, and/or features 1701-1704, 1708, 1710-1712, T1, P1, P2, P3, 1714, 1715, 1720-1728, 1730-1738, 1740, T2, 1743 and 1744 of the electronic device 1700 in FIG. 17 correspond to the respective structures, dimensions, and/or features 101-104, 108, 110-112, T1, P1, P2, P3, 114, 115, 120-128, 130-138, 140, T2, 143 and 144 described above in connection with the electronic device 100 of FIGS. 1 and 1A.

FIG. 18 shows another packaged electronic device 1800 having respective bottom and top sides 1801 and 1802, laterally opposite sides 1803 and 1804, a package structure 1808 with a mold underfill 1860, a lid 1870 on a portion of the top side of the semiconductor die 1810, a capacitor die 1840 with conductive metal pillar terminals 1843 flip-chip attached to conductive metal pillar terminals 1814 of a semiconductor die 1810, and the capacitor die 1840 is positioned between first and second substrates 1820 and 1830 according to another embodiment. The mold underfill 1860 in this example at least partially encloses the semiconductor die 1810, the substrates 1820 and 1830 and the capacitor die 1840. In one implementation, the method 200 above can include attaching the lid 1870 over at least a portion of the second side of the semiconductor die 1810. In this example, moreover, the lid 1870 extends over at least a portion of a second (e.g., top) side of the semiconductor die 1810. Apart from these noted differences and differences apparent from the figures, various structures, dimensions, and/or features 1801-1804, 1808, 1810-1812, T1, P1, P2, P3, 1814, 1815, 1820-1828, 1830-1838, 1840, T2, 1843 and 1844 of the electronic device 1800 in FIG. 18 correspond to the respective structures, dimensions, and/or features 101-104, 108, 110-112, T1, P1, P2, P3, 114, 115, 120-128, 130-138, 140, T2, 143 and 144 described above in connection with the electronic device 100 of FIGS. 1 and 1A.

FIG. 19 shows another packaged electronic device 1900 having respective bottom and top sides 1901 and 1902, laterally opposite sides 1903 and 1904, a molded package structure 1908, a capacitor die 1940 with conductive metal pillar terminals 1943 flip-chip attached to conductive metal pillar terminals 1914 of a semiconductor die 1910 and at least a portion of the capacitor die 1940 is partially exposed through the package structure 1908 along the bottom side 1901 of the electronic device 1900 according to another embodiment. Apart from these noted differences and differences apparent from the figures, various structures, dimensions, and/or features 1901-1904, 1908, 1910-1912, T1, P1, P2, P3, 1914, 1915, 1920-1928, 1930-1938, 1940, T2, 1943 and 1944 of the electronic device 1900 in FIG. 19 correspond to the respective structures, dimensions, and/or features 101-104, 108, 110-112, T1, P1, P2, P3, 114, 115, 120-128, 130-138, 140, T2, 143 and 144 described above in connection with the electronic device 100 of FIGS. 1 and 1A.

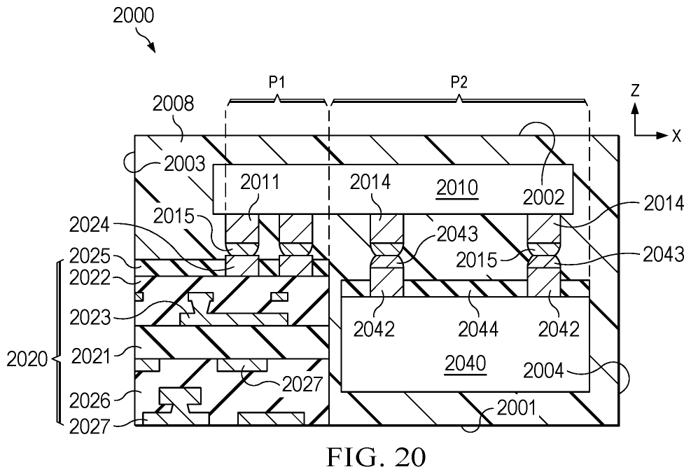

FIG. 20 shows another packaged electronic device 2000 having respective bottom and top sides 2001 and 2002, laterally opposite sides 2003 and 2004, a molded package structure 2008, a capacitor die 2040 with conductive metal pillar terminals 2043 flip-chip attached to conductive metal pillar terminals 2014 of a semiconductor die 2010. The capacitor die 2040 in this example is positioned laterally alongside a single substrate 2020 between the lateral side of the substrate 2020 and a lateral side 2004 of the electronic device 2000 according to another embodiment. Apart from these noted differences and differences apparent from the figures, various structures, dimensions, and/or features 2001-2004, 2008, 2010-2012, T1, P1, P2, P3, 2014, 2015, 2020-2028, 2040, T2, 2043 and 2044 of the electronic device 2000 in FIG. 20 correspond to the respective structures, dimensions, and/or features 101-104, 108, 110-112, T1, P1, P2, P3, 114, 115, 120-128, 140, T2, 143 and 144 described above in connection with the electronic device 100 of FIGS. 1 and 1A.

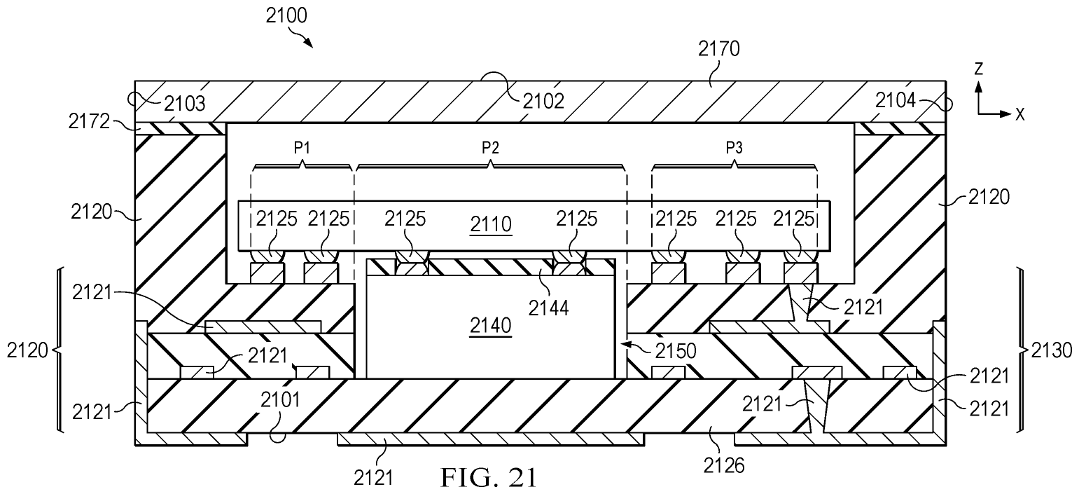

FIG. 21 shows another packaged electronic device 2100 having respective bottom and top sides 2101 and 2102, laterally opposite sides 2103 and 2104, a capacitor die 2140 with conductive features flip-chip attached to conductive metal solder portions 2125 of a semiconductor die 2110 along with a laminated organic ceramic substrate 2120 according to another embodiment. The interior of the ceramic substrate 2120 is sealed by a top lid 2170 and a seal structure 2172. The ceramic substrate 2120 has multiple laminated organic layers and conductive feature 2121 (e.g., copper, aluminum, NiAu, etc.) and provides a sealed cavity that can be evacuated, and the semiconductor die 2110 is positioned in the sealed cavity. The substrate 2120 has an opening 2150 and the capacitor die 2140 is located in the opening 2150 of the substrate 2120. Apart from these noted differences and differences apparent from the figures, various structures, dimensions, and/or features 2101-2104, 2108, 2110-2112, T1, P1, P2, P3, 2114, 2115, 2120-2128, 2140, T2, 2143 and 2144 of the electronic device 2100 in FIG. 21 correspond to the respective structures, dimensions, and/or features 101-104, 108, 110-112, T1, P1, P2, P3, 114, 115, 120-128, 140, T2, 143 and 144 described above in connection with the electronic device 100 of FIGS. 1 and 1A.

Variants of the disclosed examples are possible, for example, by substituting one, some, or all of the use of one or more ceramic capacitors with capacitor dies and vice versa, using a single substrate with an opening or side located capacitor(s) or capacitor die(s) for the use of multiple substrates, the use of ceramic organic substrates instead of multilevel package substrates or routable lead frames, etc.

FIG. 22 shows an example trench capacitor (TCAP) die 2200 that can be used the above and other implementations (e.g., the capacitor die 140 in FIGS. 1 and 1A or the other example capacitor dies illustrated and described above). In this example, as described further below, the trench capacitor die 2200 includes a trench capacitor 2230 formed in a semiconductor body 2204, 2206, 2208 of the capacitor die 2200, and conductive features 2274 along a top side of the trench capacitor die 2200 provide connections to the trench capacitor terminals as well as for other components or circuits that may be included in the trench capacitor die 2200. While the illustrated trench capacitor die 2200 in FIG. 22 includes transistors and circuits in addition to one or more externally connectable trench capacitors, other examples can include different component and/or circuit combinations, including trench capacitor dies with only capacitor components.

The trench capacitor die 2200 that serves as a capacitor die and includes two metal oxide semiconductor (MOS) transistors 2201. Disclosed examples can also include stand-alone discrete transistor semiconductor devices that have a single transistor and a trench capacitor with external conductive features that provide electrical connection to the capacitor terminals for compact connection to a main semiconductor die as described in the examples above. The transistors 2201 in FIG. 22 have single gate, source and drain finger structures. In other implementations, transistors can be built with multiple finger structures surrounding a center finger, such as source-centered configurations, drain-centered configurations, etc. The trench capacitor die 2200 in this example also includes trench capacitor structures used for isolation features, which can be omitted in other implementations. The deep trench isolation and trench capacitor concepts can be implemented in combination with any type or form of transistor, such as MOS transistors bipolar transistors, etc. In addition, various aspects of the disclosure can be used in combination with drain extended MOS transistors (not shown). Described examples include doped regions of various semiconductor structures which may be characterized as p-doped and/or n-doped regions or portions and include regions that have majority carrier dopants of a particular type, such as n-type dopants or p-type dopants.

The transistors 2201 are fabricated on and/or in a semiconductor substrate 2202. The semiconductor substrate 2202 in one example is a silicon wafer, a silicon-on-insulator (SOI) substrate or other semiconductor structure. In one example, the substrate 2202 is a p-doped silicon substrate or wafer, with a first (e.g., top) side 2203, various buried layers 2204, 2206 formed therein, and a second (e.g., bottom) side 2205. In another possible implementation, the substrate 2202 includes one or more epitaxial silicon layers (not shown) formed on a top surface, with one or more of the buried layers 2204, 2206 formed in epitaxial layers of the substrate. In the illustrated example, the substrate 2202, the buried layers 2204 and 2206, and an upper semiconductor surface layer (e.g., body region 2208) constitute a semiconductor structure. The example semiconductor structure includes a first doped layer 2206 that includes p-type majority carrier dopants. In one implementation, the p-type layer includes a portion implanted with boron to form a p-type buried layer (PBL) with an upper or top side 2207. The semiconductor surface layer 2208 extends over (e.g., directly on) the p-type buried layer 2206 and includes the upper side 2203 of the semiconductor structure. The example layer 2204 (e.g., an n-type buried layer or NBL) includes n-type majority carrier dopants. The NBL 2204 extends along the vertical Z direction from beneath the PBL 2206 toward the second side 2205. In one example, a first epitaxial silicon layer is formed over the upper surface of a silicon wafer substrate 2202, and all or a portion of the first epitaxial layer is implanted with n-type dopants (e.g., phosphorus, etc.) to form the NBL 2204. In this example, a second epitaxial silicon layer is formed over the first epitaxial layer, and all or a portion of the second epitaxial layer is implanted with p-type dopants (e.g., boron, etc.) to form the p-type buried layer 2206 with the upper side 2207. In one example, the PBL region 2206 is formed using ion implantation through the first EPI surface. The example surface layer 2208 has p-type majority carrier dopants and extends downward along the Z direction from the first side 2203.

The transistors 2201 are formed on or in the semiconductor surface layer 2208 within an active region 2210 of the semiconductor structure 2202, 2204, 2206, 2208. The example semiconductor surface layer 2208 includes p-type majority carrier dopants. The illustrated trench capacitor die 2200 includes an outer oxide isolation structure 2218 that encircles the transistor 2201 along the first (e.g., top) side 2203 in the semiconductor surface layer 2208. The oxide structure 2218 in one example is a shallow trench isolation (STI) structure, which is disposed laterally outward of the transistors 2201. In the illustrated example, the STI structure 2218 defines an end of the active region 2210 of the semiconductor substrate 2202 in which the transistors 2201 are formed.

The illustrated trench capacitor die 2200 includes a trench-based isolation structure 2220, referred to as a deep trench isolation structure. The deep trench isolation structure 2220 in FIG. 22 is adjacent to the STI structure 2218, and laterally encircles or surrounds the transistors 2201 and the active region 2210 of the semiconductor structure. The isolation structure 2220 includes a first trench 2221 that extends downward from the first side 2203 through the semiconductor structure 2202, 2204, 2206, 2208 to the buried layer 2204. The isolation structure 2220 also includes a first deep doped region 2222 with n-type majority carrier dopants (e.g., phosphorus). The first deep doped region 2222 surrounds the first trench 2221 and extends from the semiconductor surface layer 2208 to the buried layer 2204.

The isolation structure 2220 also includes a first dielectric liner that extends along the sidewall of the first trench 2221 from the semiconductor surface layer 2208 to the buried layer 2204. Any single or multilayer dielectric liner can be used. In one example, the first dielectric liner includes a first oxide layer 2223, a nitride layer 2224, and a second oxide layer 2225. The first oxide layer 2223 (e.g., silicon dioxide or SiO₂) extends along the sidewall of the first trench 2221 from the semiconductor surface layer 2208 to the buried layer 2204. The nitride layer 2224 (e.g., silicon nitride or silicon oxynitride) extends along the first oxide layer 2223 from the semiconductor surface layer 2208 to the buried layer 2204. The second oxide layer 2225 (e.g., silicon dioxide or SiO₂) extends along the nitride layer 2224 from the semiconductor surface layer 2208 to the buried layer 2204.

The isolation structure 2220 also includes a first polysilicon 2226 that extends inside the first dielectric liner 2223, 2224, 2225. The first polysilicon 2226 fills the first trench 2221 to the top side 2203 of the semiconductor surface layer 2208. The first polysilicon 2226 in one example includes p-type majority carrier dopants (e.g., boron). In the example of FIG. 22, the deep trench isolation structure 2220 is formed as a ring structure that laterally surrounds the transistors 2201. As shown in FIG. 22, the first trench 2221 has a first depth 2227 and a first width 2228. The trench capacitor die 2200 also includes shallow implant regions 2229 with n-type majority carrier dopants (e.g., a shallow n-well implanted with phosphorus). The shallow implant regions 2229 extend in the semiconductor surface layer 2208 along a side of the first trench 2221 within the first deep doped region 2222. In one example, the shallow implant is also used to form lower case n-type source/drain features (not shown) of transistors in the trench capacitor die 2200.

The illustrated trench capacitor die 2200 also includes one or more trench-based capacitors. In one example, the trench capacitor 2230 can be constructed using a single trench. In the example of FIG. 22, the capacitor 2230 includes multiple second trenches 2231 that individually extend through the semiconductor structure 2202, 2204, 2206, 2208 to the buried layer 2204. Each of the second trenches 2231 is surrounded by a second deep doped region 2232. FIG. 22 shows three trenches 2231 that extend from the first side 2203 through the semiconductor structure to the buried layer 2204. The second trench 2231 has a second depth 2237 and a second width 2238. The first width 2228 of the first (isolation) trench 2221 is greater than the second (capacitor trench) width 2238 in the device of FIG. 22. The first width 2228 of the first trench 2221 is greater than the second width 2238 of the capacitor trenches 2231. In one example, the first width 2228 of the first trench 2221 is approximately 1.5 μm, for example, from 1.35 μm to 1.65 μm, and the second width 2238 of the capacitor trenches 2231 is approximately 1.2 μm, for example, from 1.05 μm to 1.35 μm.

The example capacitor 2230 further includes second dielectric liners (e.g., layers 2233, 2234, and 2235) in each of the trenches 2231. The second dielectric liners extend along sidewalls of the second trenches 2231 from the semiconductor surface layer 2208 to the buried layer 2204. The example second dielectric liner is a multi-layer structure with a third oxide layer 2233 that extends along the sidewall of the second trench 2231 from the semiconductor surface layer 2208 to the buried layer 2204. The example second dielectric liner also includes a second nitride layer 2234 that extends along the third oxide layer 2233 from the semiconductor surface layer 2208 to the buried layer 2204, and a fourth oxide layer 2235 that extends along the second nitride layer 2234 from the semiconductor surface layer 2208 to the buried layer 2204.

The capacitor 2230 also includes a second deep doped region 2232 implanted with n-type majority carrier dopants (e.g., phosphorus). The second deep doped region 2232 surrounds the second trenches 2231 and extends from the semiconductor surface layer 2208 to the buried layer 2204. In addition, the capacitor 2230 includes a second polysilicon 2236 with p-type majority carrier dopants (e.g., boron). The second polysilicon 2236 extends inside the second dielectric liner 2233, 2234, 2235 and fills the second trench 2231 to the top side 2203 of the semiconductor surface layer 2208. The capacitor 2230 also includes a shallow implant region 2229 having majority carrier dopants of the second conductivity type. The shallow implant region 2229 extends in the semiconductor surface layer 2208 between the second trenches 2231 within the second deep doped region 2232.

The trench capacitor die 2200 includes a metallization structure that extends over the semiconductor surface layer 2208. The metallization structure includes conductive features that connect the first polysilicon 2226 to the first deep doped region 2222 for the trench-based isolation structures 2220, as well as second conductive features connected to the second polysilicon 2236 to form a first capacitor plate, and further conductive features connected to the second deep doped region 2232 to form a second capacitor plate of the capacitor 2230. The metallization structure includes a first dielectric structure layer 2254 formed over the semiconductor structure, and a multi-level upper metallization structure 2256. In one example, the first dielectric 2254 structure layer is a pre-metal dielectric (PMD) layer disposed over the transistors 2201 and the upper surface of the semiconductor structure. In one example, the first dielectric structure layer 2254 includes silicon dioxide (SiO₂) deposited over the transistors 2201, the semiconductor surface layer 2208 and the STI structures 2218. The metallization structure 2254, 2256 covers the transistors 2201 and provides internal and/or external electrical interconnection to the transistor source, drain and gate terminals.

The PMD layer 2254 includes contact structures 2260 (e.g., tungsten) that provide direct electrical connection (e.g., direct contact or connection through a silicide layer such as CoSi₂, not shown) to one or more features of the transistors 2201. The PMD material layer 2254 is formed over the illustrated structure, with contact structures 2260 formed therein to provide electrical interconnection access for one or more further upper metallization layers 2258 and 2264-2268. In one example, a silicide is formed over the top surfaces of the source, drain and gate electrode structures of the transistors 2201, and over the tops of the polysilicon features 2226, 2236 and to the deep doped regions 2222, 2232. Contacts 2260 of the PMD layer 2254 are connected to the polysilicon features 2226, 2236 and to the deep doped regions 2222, 2232 of the isolation structure 2220 and the capacitor 2230.

The upper metallization structure 2256 includes one or more layers. In the illustrated example, the upper metallization structure 2256 includes a first metallization layer 2258 formed over the PMD layer 2254, as well as further metallization layers 2264, 2265, 2266, 2267, and 2268 progressively formed over the preceding layer as shown in FIG. 22. The trench capacitor die 2200 in FIG. 22 is shown as a wafer 2270 prior to singulation and packaging, but the illustrated structure represents the described features after separated as a die for packaging. Although the trench capacitor die 2200 is an integrated circuit with multiple components, such as transistors 2201, other stand-alone discrete semiconductor device implementations can include a single transistor or other electronic component with an isolation structure 2220 and at least one capacitor 2230 or only a capacitor or multiple trench capacitors.

The upper metallization structure 2256 is a six layer structure with a first layer 2258, referred to herein as an interlayer or interlevel dielectric (ILD) layer. Different numbers of layers can be used in different implementations. In one example, the first ILD layer 2258, and the other ILD layers of the upper metallization structure 2256 are formed of silicon dioxide (SiO₂) or other suitable dielectric material. In certain implementations, the individual layers of the multi-layer upper metallization structure 2256 are formed in two stages, including an intra-metal dielectric (IMD, not shown) sub layer with conductive metal routing features or lines 2262 (e.g., aluminum, copper, etc.), and an ILD sublayer overlying the IMD sub layer with conductive contacts or plugs 2263 (e.g., tungsten vias). The individual IMD and ILD sublayers can be formed of any suitable dielectric material or materials, such as SiO₂-based dielectric materials. The first layer 2258, and the subsequent layers in the upper metallization structure 2256 include conductive metallization interconnect structures 2262, referred to as lines, formed on the top surface of the underlying layer. In this example, the first layer 2258 and the subsequent ILD layers also include conductive vias 2263, such as tungsten or aluminum that provide electrical connection from the metallization features 2262 of an individual layer to an overlying metallization layer.

The example of FIG. 22 includes a second layer 2264 disposed over the first layer 2258. The ILD layer 2258 includes conductive interconnect structures 2262 and vias 2263. The structures 2262, 2263 can be the same metal or different metals in various implementations. The individual layers can be constructed using any suitable metallization fabrication processing, such as single damascene or dual damascene processes. The illustrated structure includes further metallization levels with corresponding dielectric layers 2265, 2266 and 2267, as well as an uppermost or top metallization layer 2268. The individual layers 2265-2268 in this example include conductive interconnect structures 2262 and associated vias or contact plugs 2263.

The semiconductor structure, the electronic components (e.g., the transistors 2201), the capacitor 2230, the first dielectric structure layer 2254 and the upper metallization structure 2256 form a wafer or die 2270 with an upper side or surface 2271. The upper side 2271 of the metallization structure 2256 forms an upper side of the wafer or die 2270. The top metallization layer 2268 includes conductive features 2269, such as upper most aluminum vias. The conductive features 2269 include a side or surface at the upper side 2271 of the wafer or die 2270 at the top of the uppermost metallization layer 2268. Any number of conductive features 2269 may be provided. One or more of the conductive features 2269 can be electrically coupled with an electronic component such as one of the transistors 2201.

The upper ILD dielectric layer 2268 in one example is covered by one or more passivation layers 2273 (e.g., protective overcoat (PO) and/or passivation layers), for example, silicon nitride (SiN), silicon oxynitride (SiOₓN_{y}), or silicon dioxide (SiO₂). In one example, the passivation layer or layers 2273 include one or more openings that expose a portion of the conductive features 2269 to allow electrical connection of the features 2269 to corresponding contact structures 2274. The contact structures 2274 extend outward (e.g., upward along the “Z” direction in FIG. 22) from the upper side 2271 of the metallization structure 2256. The individual contact structures 2274 in one example include a conductive seed layer, such as copper that extends outward from the upper side 2271 of the metallization structure 2256. In one example, the contact structure 2274 includes titanium (Ti) or titanium tungsten (TiW).

The metallization structure 2254, 2256 includes first conductive features 2260, 2262 of the metallization structure 2254, 2256 that connect the first polysilicon 2226 to the first deep doped region 2222. This provides an isolation trench structure 2220 that electrically isolates the active region 2210 of the semiconductor structure from the capacitor 2230 and from other regions of the wafer or die 2270. In addition, the metallization structure includes second conductive features 2260, 2262 that are connected to the second polysilicon 2236 to form a first capacitor plate, as well as further conductive features 2260, 2262 that are connected to the second deep doped region 2232 to form a second capacitor plate. The metallization structure 2254, 2256 allows for further conductive connections (not shown) to connect the first and second capacitor plates to other circuitry within the wafer or die 2270, and/or to provide external connection for one or both of the first and second capacitor plates.

Described examples provide advantages over other EMI suppression techniques and structures for packaged electronic devices without increasing device package size for a variety of device types such as flip-chip packages and others. The described examples allow the use of similar thicknesses for the capacitor die (e.g., 140) and the substrate(s), and facilitate low loop inductance by providing significantly shorter connection loop than other approaches that attach capacitors alongside the semiconductor die on a substrate (e.g., examples can achieve <10% loop inductance in comparison by reduced distance between the semiconductor die terminals and the EMI capacitor terminals. Described examples do not rely on the substrate fabrication process to embed the EMI capacitor, and thus do not require changes or extended substrate lead time, cost, and capacity. Moreover, described example can easily accommodate changes to the desired amount of capacitance, for example, through more flexibility of the capacitor die replacement and/or substitution of different ceramic capacitors during manufacturing. In certain examples, the molding process helps to mechanically hold and/or support the capacitor die and fully cover the capacitor die in certain implementations. Described examples can be implemented in BGA products (EP. ASC, etc.), and flip-chip ceramic products or other product types and forms to enhance the EMI performance. Certain described examples provide an embedded way to add one or more capacitors for flip-chip packaging and other package types during the assembly process. Also, described examples can include more than one laminate substrate to facilitate the capacitor integration.

Modifications are possible in the described examples, and other implementations are possible, within the scope of the claims.

What is claimed is:

1. An electronic device, comprising:
a semiconductor die having a side, first conductive terminals along a first portion of the side, and second conductive terminals along a second portion of the side;
a substrate having conductive features facing the first portion of the side of the semiconductor die and electrically coupled to respective ones of the first conductive terminals;
a capacitor die or a ceramic capacitor having conductive capacitor terminals facing the second portion of the side of the semiconductor die and electrically coupled to respective ones of the second conductive terminals; and
a package structure that at least partially encloses the semiconductor die, the substrate and the capacitor die or ceramic capacitor.

2. The electronic device of claim 1, wherein:
the semiconductor die has third conductive terminals along a third portion of the side;
the substrate is a first substrate;
the electronic device further comprises a second substrate having second conductive features facing a third portion of the side of the semiconductor die and electrically coupled to respective third conductive terminals; and
the capacitor die or ceramic capacitor is located between the first and second substrates.

3. The electronic device of claim 1, wherein:
the substrate has an opening; and
the capacitor die or ceramic capacitor is located in the opening of the substrate.

4. The electronic device of claim 1, wherein the substrate is a multilevel package substrate.

5. The electronic device of claim 1, wherein the substrate is a laminated organic ceramic substrate.

6. The electronic device of claim 1, wherein:
the second conductive terminals are conductive metal pillars that extend outward from the second portion of the side of the semiconductor die;
the capacitor die or ceramic capacitor is a capacitor die; and
the conductive capacitor terminals are further conductive metal pillars that extend toward, and are soldered to, respective ones of the conductive metal pillars.

7. The electronic device of claim 6, wherein the capacitor die includes a trench capacitor formed in a semiconductor body of the capacitor die.

8. The electronic device of claim 6, wherein the first conductive terminals are conductive metal pillars that extend outward from the first portion of the side of the semiconductor die.

9. The electronic device of claim 1, wherein the conductive capacitor terminals of the capacitor die or ceramic capacitor are solder bumps.

10. The electronic device of claim 1, wherein the second conductive terminals are solder bumps.

11. The electronic device of claim 1, wherein the capacitor die or ceramic capacitor is a ceramic capacitor.

12. The electronic device of claim 1, wherein the package structure includes:
a first molded structure that at least partially encloses the semiconductor die and the substrate; and
a mold underfill at least partially encloses the semiconductor die, the substrate and the capacitor die or ceramic capacitor.

13. The electronic device of claim 1, wherein:
the package structure includes a mold underfill at least partially encloses the semiconductor die, the substrate and the capacitor die or ceramic capacitor; and
the electronic device further comprises a lid over at least a portion of a second side of the semiconductor die.

14. The electronic device of claim 1, wherein at least a portion of the capacitor die or ceramic capacitor is exposed outside the package structure.

15. The electronic device of claim 1, wherein the capacitor die or ceramic capacitor located between the substrate and a side of the package structure.

16. A system, comprising:
a circuit board; and
an electronic device having a semiconductor die, a substrate, a capacitor die or a ceramic capacitor, and a package structure, wherein:
the semiconductor die has a side, first conductive terminals along a first portion of the side, and second conductive terminals along a second portion of the side;
the substrate has conductive features facing the first portion of the side of the semiconductor die and electrically coupled to respective ones of the first conductive terminals;
the capacitor die or a ceramic capacitor has conductive capacitor terminals facing the second portion of the side of the semiconductor die and electrically coupled to respective ones of the second conductive terminals; and
the package structure at least partially encloses the semiconductor die, the substrate and the capacitor die or ceramic capacitor.

17. A method of fabricating an electronic device, the method comprising:
attaching conductive capacitor terminals of a capacitor die or a ceramic capacitor to respective second conductive terminals of a semiconductor die;
attaching first conductive terminals of the semiconductor die to respective conductive features of a substrate; and
forming a package structure that at least partially encloses the semiconductor die, the substrate and the capacitor die or ceramic capacitor.

18. The method of claim 17, wherein forming the package structure includes forming a mold underfill at least partially encloses the semiconductor die, the substrate and the capacitor die or ceramic capacitor.

19. The method of claim 18, further comprising attaching a lid over at least a portion of a second side of the semiconductor die.

20. The method of claim 17, wherein:
attaching the conductive capacitor terminals of the capacitor die or ceramic capacitor to the respective second conductive terminals of the semiconductor die includes performing a first flip-chip die attach process; and
attaching the first conductive terminals of the semiconductor die to the respective conductive features of the substrate includes performing a second flip-chip die attach process.
